(19) United States
(12) Patent Application Publication
(10) Pub. No.: US 2003/0211740 A1
(43) Pub. Date: Nov. 13, 2003

(54) Apparatus and method for manufacturing semiconductor devices

(76) Inventors: In-Ho Bang, Chung Cheong Nam-Do (KR); Woo-Young Kim, Chung Cheong Nam-Do (KR)

Correspondence Address: KEUSEY, TUTUNJIAN & BITETTO, P.C., 14 VANDERVENTER AVENUE, SUITE 128, PORT WASHINGTON, NY, 11050, US

(21) Appl. No.: 10/417,961

(22) Filed: Apr. 17, 2003

(30) Foreign Application Priority Data
May 10, 2002 (KR) 10-2002-25773

(51) Int. Cl. C30B 1/00; H01L 21/302; H01L 21/461

(52) U.S. Cl. 438/689; 117/204

(57) ABSTRACT

The present invention includes an apparatus for manufacturing a semiconductor having a position amending device, an elevating device, a nozzle, a nozzle moving device and a flat zone alignment device. A wafer is transferred into the apparatus for manufacturing a semiconductor and placed at the right position to be exactly located at a center of the chuck. In addition, the flat zone alignment device aligns the flat zone to face one direction. The nozzle may be moved to easily adjust an etching width of an edge of the wafer and to etch the flat zone thereof so it is etched to a uniform etching width about the edge of the wafer.

### FIELD OF THE INVENTION

The present invention generally relates to a device for manufacturing a semiconductor and, more specifically, to a device of injecting a fluid at an edge of a wafer.

### BACKGROUND OF THE INVENTION

Conventionally, a plurality of layers, such as a poly crystalline layer, an oxide layer, a nitride layer and a metallic layer, are formed on a wafer (i.e., a semiconductor substrate) in a process for fabricating a semiconductor device. A photoresist layer is coated on the above layers and then patterns formed on a mask are transcribed on the photoresist layer by a photolithographic process. So that desirable patterns are formed on the wafer through an etching process.

During these processes, the wafer is transferred to a next step after each step is completed. The wafer is typically transferred with the edge thereof held by a transfer apparatus. In this case, the layers on the edge of the wafer may be separated and scattered, thereby contaminating the center surface of the wafer or the surface of other wafers. As a result, yield is decreased. To prevent this, it is necessary to remove the layers from the edge of the wafer.

Typically, the following two methods have been used to etch the edge of the wafer.

First, the region that needs to be etched (i.e., some region including patterns) is protected with chemicals or a mask and then the wafer is etched. However, the first method takes a long time to complete because the region where the patterns are formed is protected with the chemicals and the mask. The protectors need to be removed after etching. The etchant is wasted since the etchant is injected over the entire surface of the wafer.

Second, the wafer is inversely installed on a chuck for patterns on the wafer to face the chuck. The etchant is injected on the wafer through a nozzle to etch the edge of the wafer. Etching width is adjusted for an amount of nitrogen gas, so that it is difficult to etch the edge of the wafer in an exact etching width. Also, in case a wafer has a flat zone, the flat zone cannot be etched to a uniform width.

The above-mentioned two methods suffer from additional problems as follows. Generally, the wafer is installed on the chuck by a transfer apparatus such as a robot arm. When the wafer is not exactly installed at the center of the chuck (i.e. there is a distance between the centers of the wafer and the chuck), the edge of the wafer is over or under etched since the etchant is not uniformly spread on the edge of the wafer.

### SUMMARY

Some embodiments of the present invention provide an apparatus for manufacturing a semiconductor to install a wafer precisely at the center of a chuck.

Other embodiments of the present invention provide an apparatus for manufacturing a semiconductor to easily adjust an etching width of the edge of the wafer and to etch a flat zone of the wafer for a uniform etching width.

In any of the above embodiments, the apparatus for manufacturing a semiconductor may include a vacuum chuck, a position amending device and a first nozzle. The vacuum chuck is where a wafer is placed. The position amending device may include pins for moving the wafer to an improved position so as to be laid precisely at the center of the chuck. The first nozzle injects a fluid at the edge of the wafer.

Preferably, the position amending device has first through fourth pins disposed in four directions and a transfer device for moving the first through fourth pins to a predetermined position. The transfer device includes a first connecting rod, a second connecting rod, a first moving rail, a first driving part and a first stopper. The first and second pins are combined with the first connection rod and the third and fourth pins are combined with the second connecting rod. The first moving rail guides movement of the first and second connecting rods. The first driving part drives the first and second connecting rods. The first stopper limits movements of the first and second connecting rods.

Preferably, each of the first through fourth pins has a groove around it to hold the wafer, wherein the groove contacts a side of the wafer. The first through fourth pins are installed on the first and second connecting rods and rotated about their respective central axis.

The apparatus further comprises a flat zone alignment device that aligns the flat zone of the wafer to face predetermined direction. The flat zone alignment device includes a parallel pin, a first bracket, a first feeding bar and a second driving part. The parallel pin has a parallel surface. The parallel pin is fixed in the first bracket, and the first bracket is fixed in the first feeding bar. The second driving part moves the first feeding bar. The flat zone alignment device pushes one edge of the flat zone to rotate the wafer until the flat zone of the wafer is contacted with the parallel surface of the parallel pin.

The apparatus may further comprise an elevating device that moves the position amending plate up and down. The elevating device preferably includes a second feeding bar, a third driving part, a guide and a second stopper. The second feeding bar is fixed to the position amending device and the third driving part drives the second feeding bar. The guide leads a movement of the position amending device. The second stopper prevents the position amending device from being transferred over than a predetermined distance.

The apparatus may further comprise a first nozzle moving device that moves the first nozzle. The first nozzle moving device includes a second bracket, a base and a fourth driving part. The first nozzle is combined with the second bracket. The base has a second moving rail that leads a movement of the second bracket. The fourth driving part moves the bracket combined with the first nozzle.

The first nozzle has an inserted part having an upper side and a lower side and the inserted part is where the edge of the wafer is inserted. A first injection hole is formed in the upper side of the inserted part and a suction hole is formed in the lower side of the inserted part. Preferably, a second injection hole is formed in the upper and lower sides of the inserted part, respectively. The second injection hole injects gases to prevent a fluid sprayed through the first injection hole from flowing out of the inserted part. Moreover, third injection holes are formed in the bottom at the front part of the top body and in the top of the front part of the bottom body, respectively. The third injection holes inject cleaning chemicals to clean the edge of the wafer.

The apparatus may further comprise a second nozzle and a second nozzle moving device. The second nozzle preferably injects cleaning chemicals to clean the edge of the wafer that reacts with the fluid injected through the first nozzle. The second nozzle moving device transfers the second nozzle. Preferably, the first nozzle injects the etchant at the edge of the wafer. The position amending device preferably further includes a fourth injection hole. The fourth injection hole injects gases to prevent the fluid injected through the first nozzle from flowing out of the first nozzle.

The first nozzle is preferably moved during etching of the flat zone of the wafer to etch the flat zone in a uniform etching width.

According to the present invention, a method for etching an edge of a wafer may include the following steps. The wafer is transferred over a chuck and then an elevating device moves the position amending device to place the wafer among first through fourth pins. The pins are moved to place the wafer at a centered position and then the pins hold the wafer. The position amending device is moved to put the wafer on the chuck. Then, the edge of the wafer is etched.

The step of placing the wafer at the centered position and holding the same with the pins includes the following steps. The first and second pins are moved to a predetermined position. The third and fourth pins are moved toward a predetermined position to push the wafer, thereby placing the wafer at the centered position and holding the wafer.

Preferably, when the wafer has a flat zone, a step of aligning the flat zone of the wafer may be further included. In this case, the wafer is at the amended position and held by the pins. Aligning the flat zone is a parallel pin installed on a flat zone alignment device which is moved toward the flat zone to push one edge thereof. Therefore, the wafer is rotated until the parallel pin contacts with the flat zone of the wafer in a plane.

Preferably, etching the edge of the wafer includes the following. The first nozzle is moved straight to insert the wafer into the inserted part. The suction hole is opened to compulsorily suck the air around. An etchant is injected through the first nozzle and the wafer is rotated. The etchant is sucked into the suction hole.

A step of injecting gases through the third injection hole is preferably provided in order to prevent the etchant from flowing out of the inserted part of the first nozzle.

### BRIEF DESCRIPTION OF THE DRAWINGS

FIG. 1 is a perspective view showing an apparatus for manufacturing a semiconductor.

FIG. 2 is a front view of FIG. 1.

FIG. 3 is a perspective view showing a position amending device.

FIG. 4 is a top view of FIG. 3

FIGS. 5A-5D are views showing sequential movements of pins for placing the wafer in a centered position according to an example.

FIGS. 6A-6D are views showing sequential movements of pins for placing the wafer in the centered position according to another example.

FIG. 7 is a perspective view showing a flat zone alignment device.

FIG. 8 is a front view of FIG. 7.

FIGS. 9A-9C are views showing alignment step of the flat zone of the wafer.

FIG. 10 is a perspective view showing an elevating device combined with the position amending device.

FIG. 11 is a perspective view showing a first nozzle moving device combined with the first nozzle.

FIGS. 12A and 12B are a front view and a top view showing the first nozzle moving device combined with the first nozzle.

FIG. 13 is a perspective view showing the first nozzle.

FIG. 14 is a cross-sectional view of FIG. 13.

FIG. 15 is a view showing a moving path of the etchant injected to the edge of the wafer.

FIG. 16 is a flow chart showing steps of etching the edge of the wafer.

### DETAILED DESCRIPTION OF PREFERRED EMBODIMENTS

The present invention will be described more fully hereinafter with reference to the accompanying drawings, in which preferred embodiments of the invention are shown. This invention, however, may be embodied in many different forms and should not be construed as limited to the embodiments set forth herein. Rather, these embodiments are provided as examples to demonstrate the present invention to those skilled in the art.

In the following preferred embodiment, an apparatus for etching an edge of a wafer 10 serves as an example. However, the apparatus according to the present invention may be used in all kinds of devices for manufacturing a semiconductor, e.g., the apparatus for placing the wafer 10 on a chuck 800 and injecting a fluid to the wafer 10 through a nozzle.

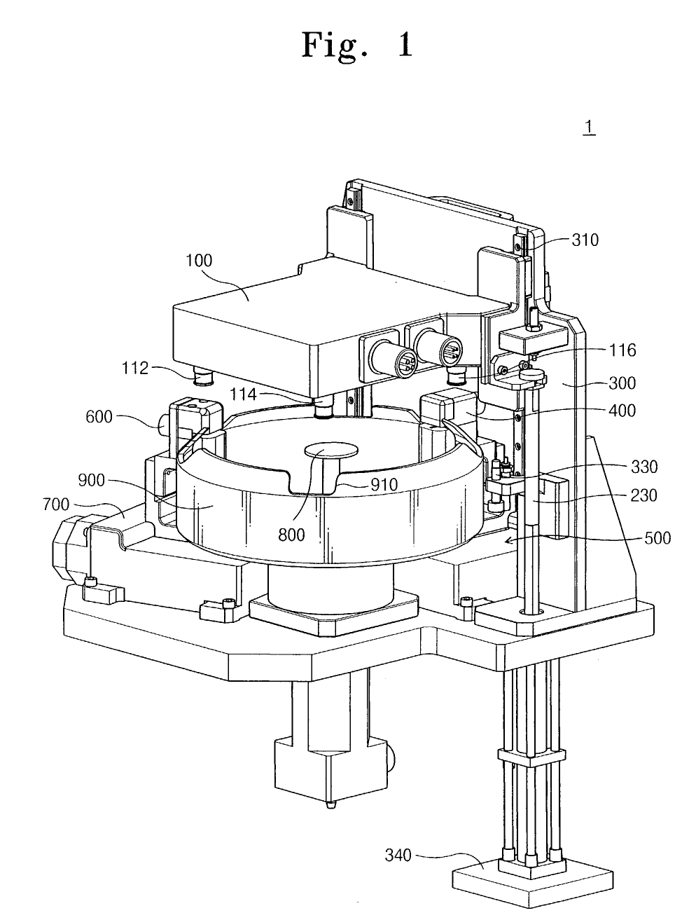

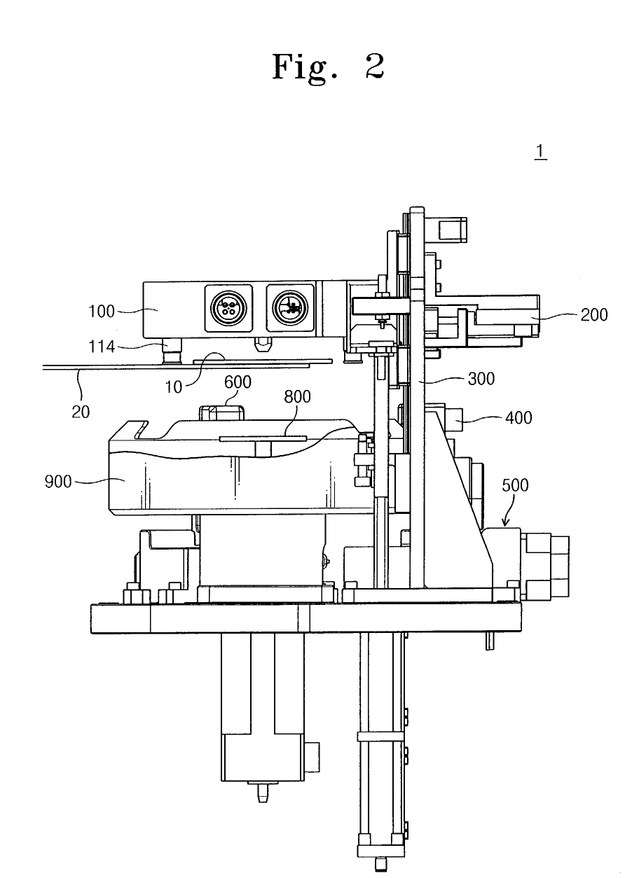

FIG. 1 is a perspective view of an apparatus for manufacturing a semiconductor and FIG. 2 is a front view of the same.

Referring to FIGS. 1 and 2, an apparatus 1 for manufacturing a semiconductor comprises a chuck 800, a position amending device 100, an elevating device 300, a first nozzle 400, a first nozzle moving device 500, a second nozzle 600, a second nozzle moving device 700 and a flat zone alignment device 200. The chuck 800 is located in a chamber 900 in order to prevent an operation environment from being contaminated due to splashing of an etchant. The chamber 900 is open at an upper part and has grooves 910 at an upper portion of a side wall. The first nozzle 400 and the second nozzle 600 are moved toward the wafer 10 inside the chamber 900 from outside of the chamber through the grooves 910.

The position amending device 100 locates the wafer 10 at a right or centered position. The position amending device 100 combines with the elevating device 300 to be transferred up and down along the elevating device 300. The wafer 10, which is located at the right position, is placed on the chuck 800 by the position amending device 100. The right or centered position is defined as the wafer' position that a center of the wafer 10 is exactly located at a center of the chuck 800.

The first nozzle 400 injects an etchant to etch the edge of the wafer 10. The first nozzle 400 may be moved by the first nozzle moving device 500 during the etch process. Thereby, an etching width of the edge of the wafer 10 can be easily adjusted and the flat zone 12 of the wafer 10 may be etched with an identical width. The second nozzle 600 is used for cleaning the edge of the etched wafer 10 by the etchant and moved by the second nozzle moving device 700.

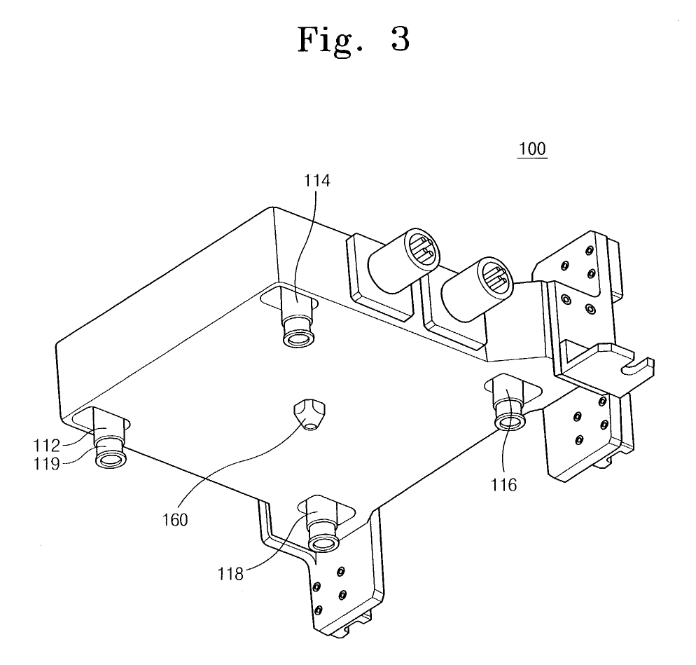

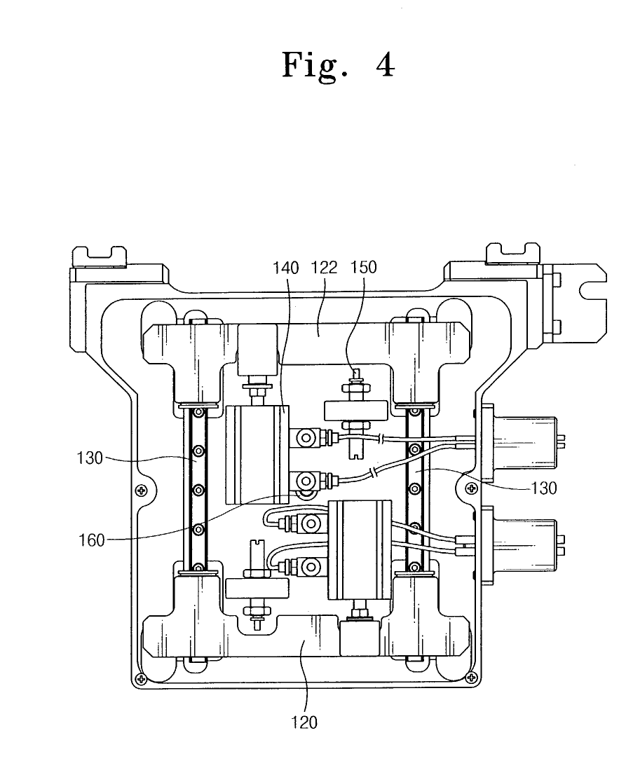

FIG. 3 is a perspective view showing a position amending device 100 in accordance with the present invention and FIG. 4 is a top view of FIG. 3.

Referring to FIGS. 3 and 4, the position amending device 100 includes first through fourth pins 112, 114, 116 and 118, a first connecting rod 120, a second connecting rod 122, a first moving rail 130, a first stopper 150 and a first driving part 140.

The position amending device 100 may be square-shaped and may have four pins 112, 114, 116 and 118 protruding downward. The first pin 112 and the second pin 114 are fixed at each end of the first connecting rod 120. The third pin 116 and the fourth pin 118 are fixed at each end of the second connecting rod 122. The first connecting rod 120 and the second connecting rod 122 are installed with the first moving rail 130 in a moving structure. The first connecting rod 120 and the second connecting rod 122 are moved along the first moving rail 130 by the first driving part 140. In a preferred embodiment, a pneumatic cylinder is used as the first driving part 140 but other driving devices, such as a stepping motor, may also be used. The first driving part 140 moves the first and second connecting rods 120 and 122 up to a predetermined distance. The first stopper 150 is installed at the position amending device 100 to limit movements of the first and second connecting rods 120 and 122 to a predetermined distance.

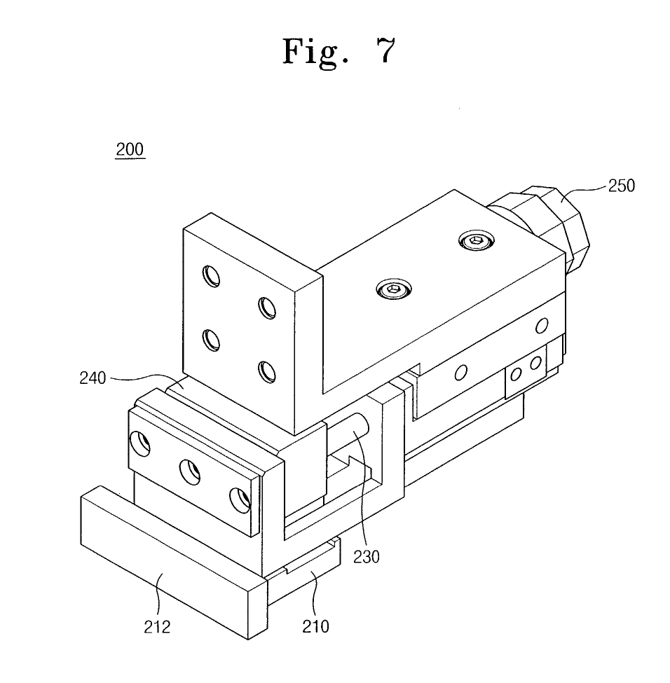

In FIG. 4, the first and second pins 112 and 114 fixed at the first connecting rod 120 are moved at the same time. The third and fourth pins 116 and 118 fixed at the second connecting rod 122 are moved at the same time. Moreover, the first connecting rod 120 and the second connecting rod 122 are moved toward each other. However, each of the first though fourth pins 112, 114, 116, and 118 may be moved independently or may be moved toward a center of the wafer 10 (i.e., a cross direction) as illustrated in FIG. 6. A groove 119 is formed around each of the first through fourth pins 112, 114, 116 and 118 to stably hold the wafer 10.

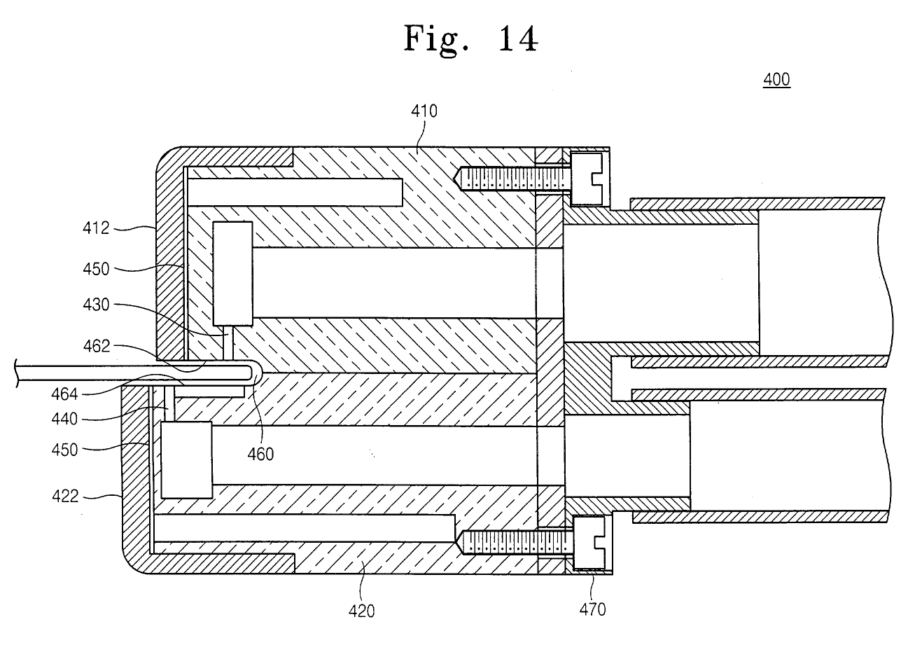

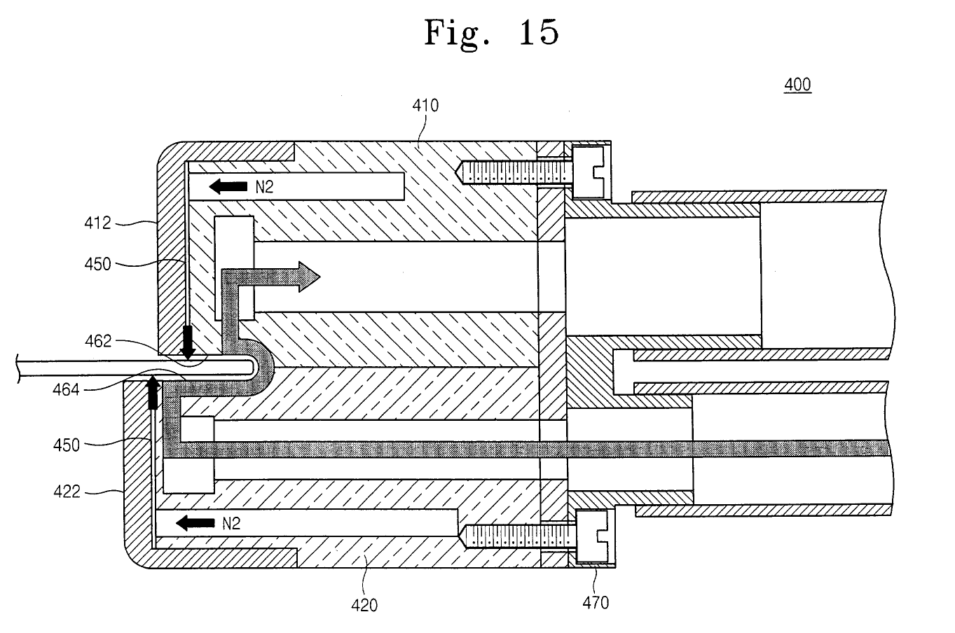

The position amending device 100 may have a fourth injection hole 160 which injects hydrogen gas to prevent the sprayed etchant from flowing out of an inserted part 460 of the first nozzle 400 (see FIG. 14). In this case, a pipe (not shown) is included in the position amending device 100.

The wafer 10 is transferred downward by a transfer unit 20 such as a robot arm so as to be apart from the position amending device 100 a predetermined distance. The position amending device 100 is transferred along a guide 310 of the elevating device 300 so that the wafer 10 is disposed among the pins 112, 114, 116 and 118. The position amending device 100 moves the wafer 10 placed on the transfer apparatus 20 at the right position. Then, the wafer 10 is held by the position amending device 100 and the transfer unit 20 is conveyed outside the apparatus 1 for additional semiconductor manufacturing processes. The transfer unit 20 preferably has enough space to amend the position of the wafer on the transfer apparatus 20.

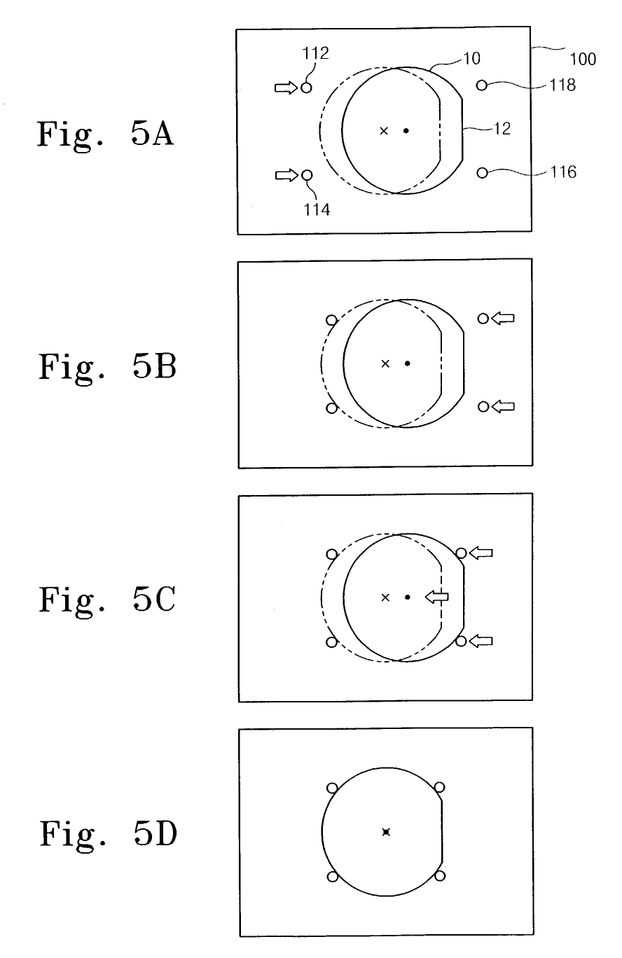

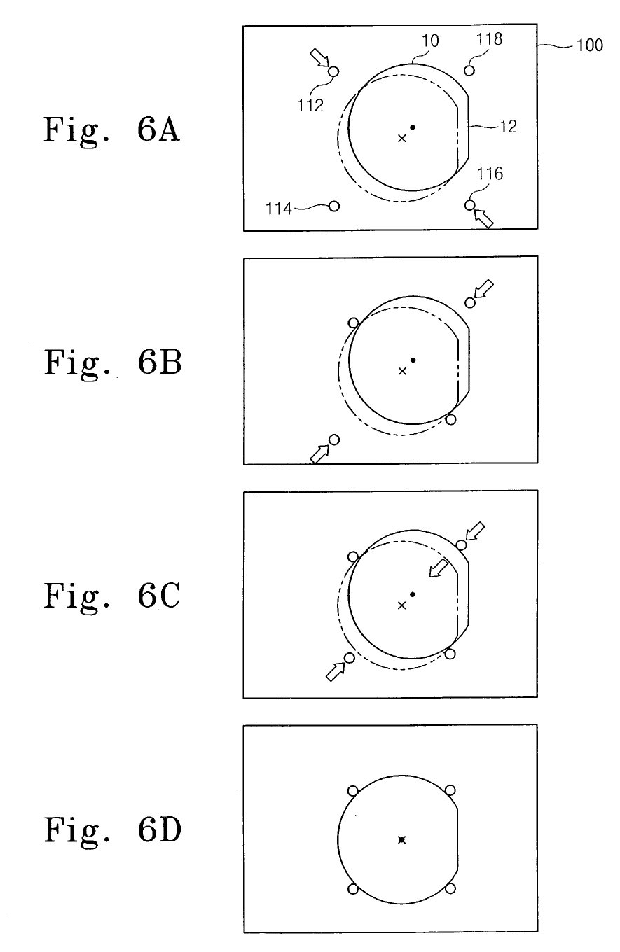

FIGS. 5A-5D and 6A-6D show that the position amending device 100 places the wafer 10 at the right position. In FIGS. 5A-5D and 6A-6D, a wafer 10, which is initially placed, is illustrated as a solid line. A wafer 10 moved to the right position is illustrated as a dotted line. Also, the center of the wafer 10 illustrated as a dotted line is marked with “x” and a center of the wafer 10 illustrated as a solid line is marked with “•”.

FIGS. 5A-5D show that the first connecting rod 120 and the second connecting rod 122 are moved toward each other to place the wafer 10 at the right position.

The wafer 10 is disposed among the pins 112, 114, 116 and 118 misaligned from the right position (FIG. 5A). In order to locate the wafer 10 to the right position, the first and second pins 112 and 114 are moved horizontally a predetermined distance (FIG. 5B). Then, the third and fourth pins 116 and 118 are moved toward the wafer's position (FIG. 5C). While the third and fourth pins 116 and 118 are moved toward the predetermined position, the third and fourth pins 116 and 118 push the wafer 10. The wafer 10 is thereby moved toward the right position with the third and fourth pins 116 and 118 (FIG. 5D).

The wafer 10 transferred by the transfer apparatus may be off-center from the right position. In this case, the first and second pins 112 and 114 make prior contact with the wafer 10 to push the wafer 10 toward the third and fourth pins 116 and 118.

FIGS. 6A-6D show that the first through fourth pins 112, 114, 116 and 118 are moved toward “x” (i.e., a center of the wafer 10 at the right position).

The wafer 10 is disposed among the pins 112, 114, 116 and 118 off-center from the right position (FIG. 6A). The first and third pins 112 and 116 are moved toward a predetermined position (FIG. 6B). Then, the second and fourth pins 114 and 118 are moved toward the wafer's position (FIG. 6C). One of the second pin 114 and the fourth pin 118 makes contact with the wafer 10 while being moved and moves the wafer 10 toward the right position. The wafer 10 is placed at the right position through the mentioned process and held by the first through four pins 112, 114, 116 and 118 (FIG. 6D).

While the present invention shows four pins other configurations with different numbers of pins are contemplated, e.g., embodiments may include three, five, or six pins.

The wafer 10, which is placed and held by the position amending device 100, is aligned by the flat zone alignment device 200 for flat zones 12 to face one direction. The flat zones 12 are aligned to face one direction, so that all the subsequent processes may be performed in common with less error.

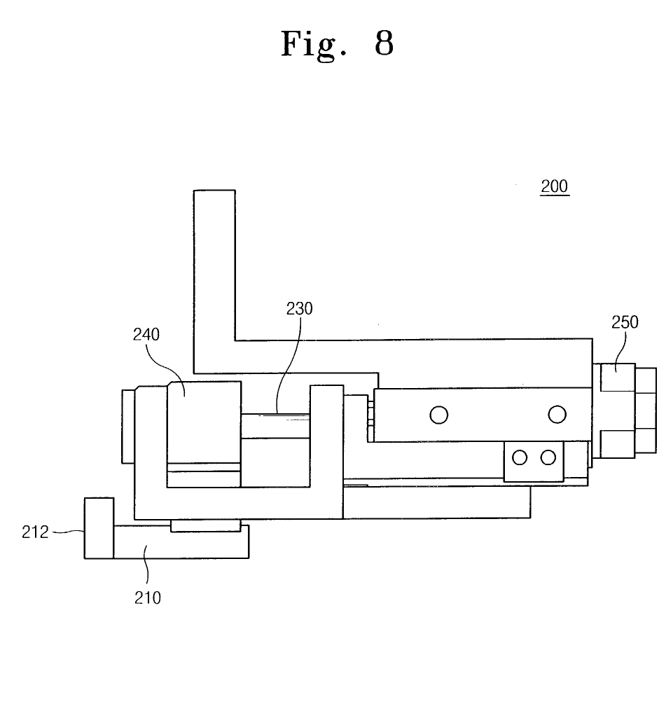

FIG. 7 is a perspective view showing the flat zone alignment device 200 and FIG. 8 is a top plane view of the same.

Referring to FIGS. 7 and 8, the flat zone alignment device 200 includes a parallel pin 210, a first bracket 240, a first feeding bar 230 and a second driving part 250.

The flat zone alignment device 200 has a parallel surface. The parallel pin 210 is fixed to the first bracket 240 and the first bracket 240 is connected to the first feeding bar 230. The first feeding bar 230 is moved by the second driving part 250. The flat zone alignment device 200 is preferably combined with the position amending device 100. The flat zone alignment device 200 may be disposed apart from the position amending device 100.

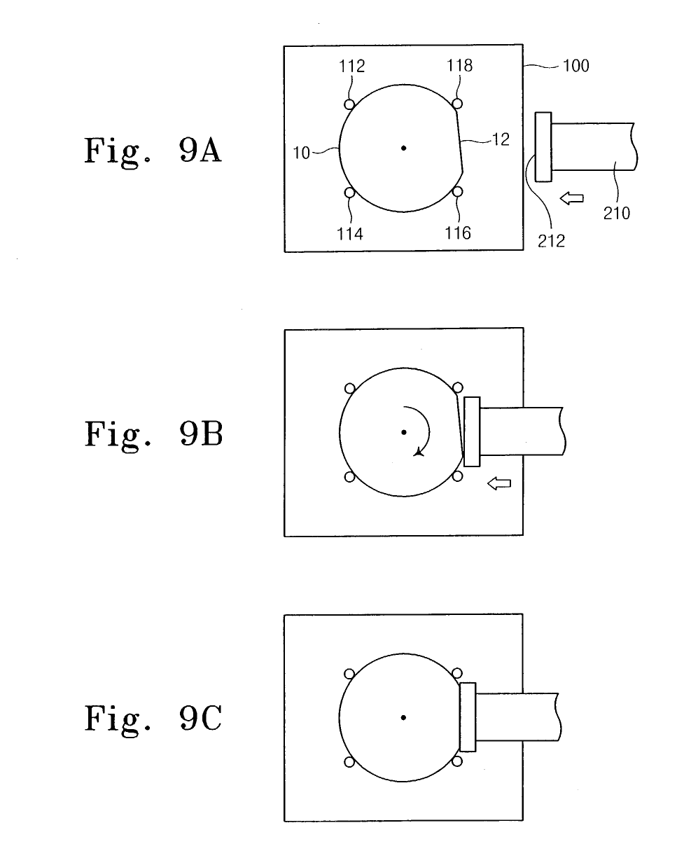

Referring to FIGS. 9A-9C, steps of aligning the flat zone of the wafer 10 will be explained hereinafter.

The wafer is held by the pins (112-118). The wafer's flat zone may be skewed relative to surface 212 (FIG. 9A). The parallel pin 210 is moved straight toward the wafer 10 and one edge of the flat zone is in line-contact with the parallel surface 212 of the parallel pin 210 (FIG. 9B). Then, the parallel pin 210 continuously moves, so that the wafer 10 held by the pins rotates until the wafer 10 is in plane-contact with the parallel surface 212 (FIG. 9C). Through this process, the flat zone is aligned in the desired or predetermined direction.

Preferably, the pins 112, 114, 116 and 118 may rotate on the first and second connecting rods 120 and 122 about their own central axes so as to decrease friction between the pins and the rotating wafer 10.

The position amending device 100 is transferred downward by the elevating device 300 to lay the wafer 10 on the chunk 800. The wafer 10 is changed in position and flat zone thereof is aligned to surface 212. The elevating device 300 transfers the position amending device 100 up and down.

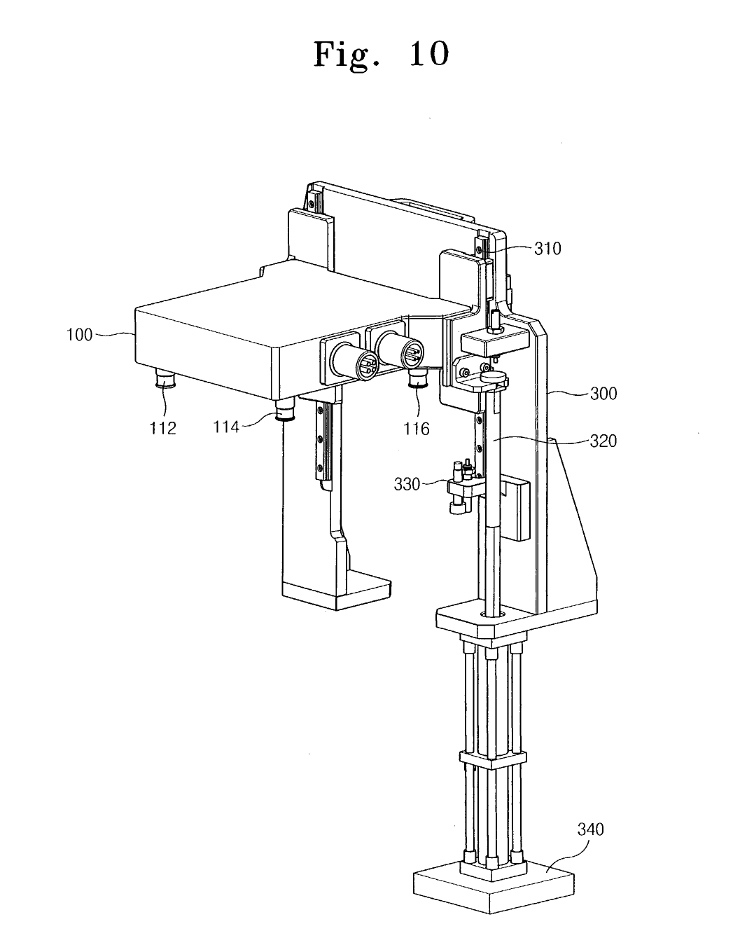

FIG. 10 shows the elevating device 300 combined with the position amending device 100. Referring to FIG. 10, the elevating device 300 includes a guide 310, a second feeding bar 320, a second stopper 330 and a third driving part 340.

The guide 310 leads the position amending device 100 to permit up and down motion. The second feeding bar 320 is combined with the position amending device 100. The third driving part 340 transfers the second feeding bar 320 up and down to move the position amending device 100 along the guide 310. The elevating device 300 includes the second stopper 330 to prevent the position amending device 100 from moving beyond the predetermined position. A stepping motor or a pneumatic or hydraulic cylinder may be used as the third driving part 340.

The edge of the wafer 10 on the chuck 800 is etched by an etchant injected from the first nozzle 400. The first nozzle 400 accurately adjusts an etching width on the wafer 10. The first nozzle moving device 500 transfers the first nozzle 400 to etch the flat zone 12 to a uniform etching width during process.

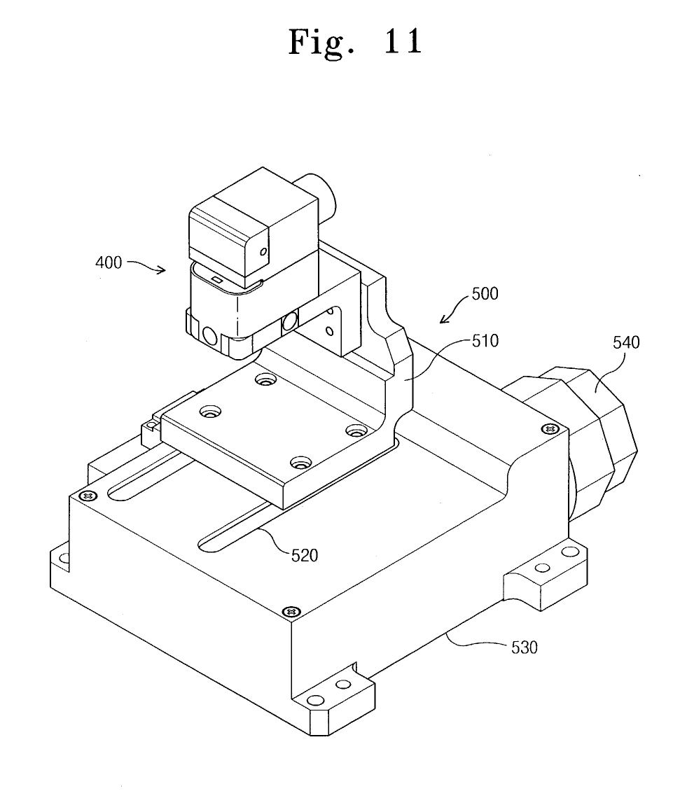

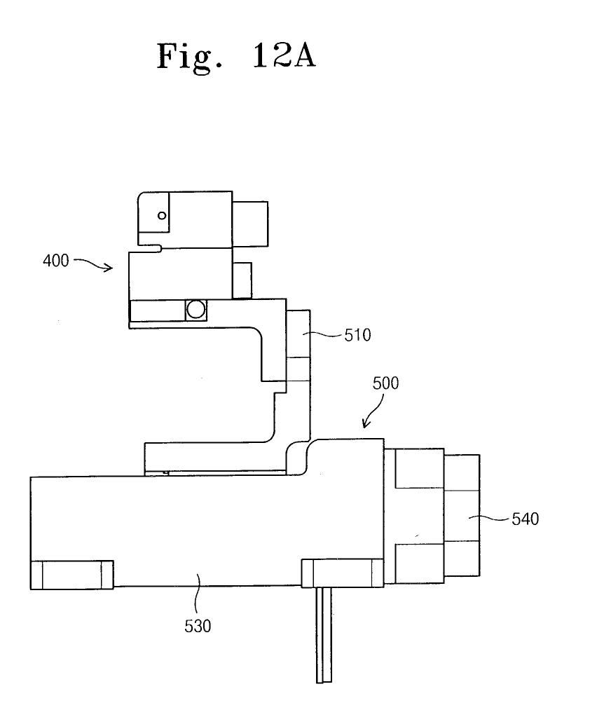

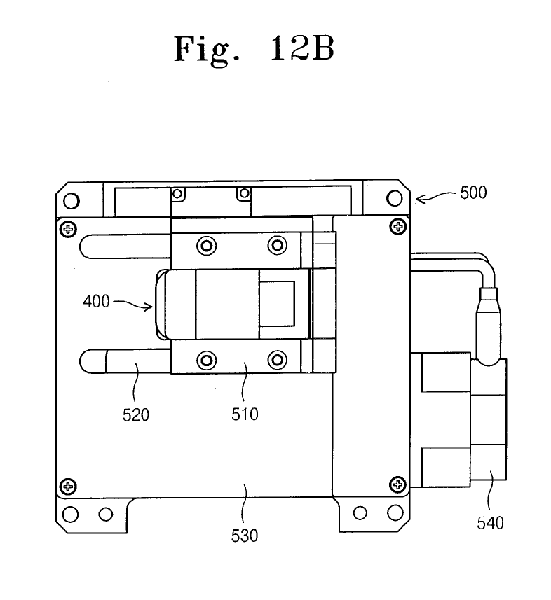

FIG. 11 is a perspective view showing a first nozzle moving device of the apparatus 1 for manufacturing a semiconductor. FIGS. 12A and 12B are a front view and a top view, respectively, of the first nozzle moving device 500. The first nozzle moving device 500 will be explained hereinafter, according to FIGS. 11, 12A and 12B.

The first nozzle moving device 500 includes a second bracket 510, a base 530, a second moving rail 520 and a fourth driving part 540. The first nozzle 400 is fixed to the second bracket 510. The second moving rail 520 is disposed on the base 530, and the second bracket 510 combines with the base 530 to move on the second moving rail 520. The second bracket 510, where the first nozzle 400 is fixed, is moved on the second moving rail 520 by the fourth driving part 540.

Thus, the first nozzle 400 is moved by the first nozzle moving device 500 to insert the edge of the wafer 10 into the inserted part 460 of the first nozzle 400. The edge of the wafer may be inserted into the inserted part 460 for a different width depending on an etching width. In addition, the first nozzle 400 is fastened when the edge of the wafer (except for the flat zone) is etched. However, the first nozzle 400 moves to etch the edge of the flat zone for a uniform width when the flat zone is etched. In this case, the wafer is rotated by a spin chuck.

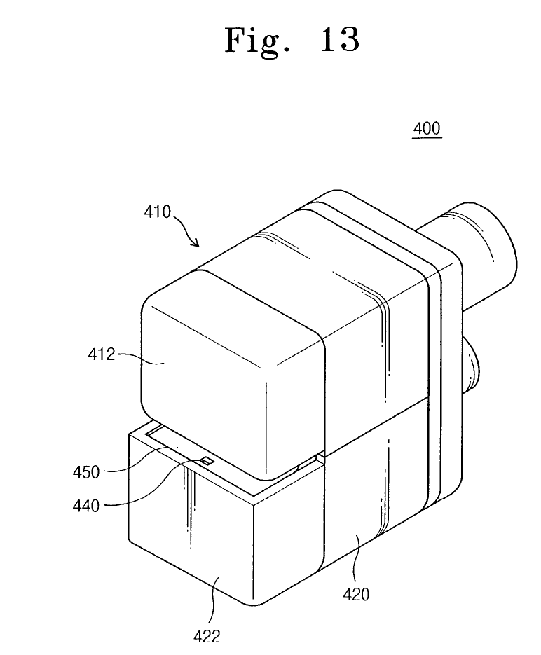

The first nozzle 400 is explained hereinafter. FIG. 13 is a perspective view of the first nozzle 400, and FIG. 14 is a cross-sectional view of the first nozzle 400. FIG. 15 shows a moving pass of the etchant injected to the edge of the wafer 10.

*Referring to FIGS. 13 and 14, the first nozzle 400 comprises a top body 410, a bottom body 420 and third brackets 470. The top body 410 and the bottom body 420 are connected by the third brackets 470. The first nozzle 400 has the inserted part 460 where the edge of the wafer is inserted. The inserted part 460 is formed at front of the first nozzle 400. The inserted part 460 comprises an upper side 462 and a lower side 464.

Referring to FIG. 14, a first injection hole 440 is formed in the lower side 464 of the inserted part 460. Through the first injection hole, an etchant is sprayed to the edge of the wafer 10. In the upper side 462 of the inserted part 460, a suction hole 430 is preferably formed.

The suction hole 430 may be formed in the lower side 464 of the inserted part 460 and the first injection hole 440 may formed in the upper side 462 thereof.

The first nozzle 400 injects nitrogen gas through the second injection hole 450 in order to prevent the etchant from flowing out of the inserted part 460. The first nozzle 400 comprises a first cover 412 and a second cover 422 in order to form the second injection hole 450. The first cover 412 is combined to a front of the top body 410 and spaced apart a predetermined distance. The second cover 422 is combined to a front of the bottom body 420 and spaced apart a predetermined distance. Thus, the second injection hole 450 may be formed in each of the upper side 462 and the lower side 464 of the inserted part 460 without the first and second covers 412 and 422. The second injection holes 450 are preferably formed at the outside of the first injection hole 440 and the suction hole 430.

Referring to FIG. 15, steps in which the etchant is injected through the first nozzle 400 and etches the edge of the wafer 10 is shown.

A chemical supplier (not shown) outside the first nozzle 400 provides the etchant to the first nozzle 400 and the etchant is injected through the first injection hole 440 to the inserted part 460. The etchant etches the edge of the back and front sides of the wafer and the sidewall thereof. Then, the etchant is sucked into the suction hole 430 to be ejected outward.

While the etchant is injected through the first injection hole 440, the hydrogen gas is injected through the second injection hole 450 to form a barrier layer. Thus, the etchant does not flow out of the inserted part 460 because of the barrier layer.

According to the present invention, nitrogen gas is injected from the first nozzle 400 or the fourth nozzle 160 of the position amending device 100 to prevent the etchant from flowing out of the first nozzle 400. Thus, the part not to be etched (i.e., the part where a pattern is formed) need not be protected by chemicals or a mask, so that operating time may be decreased and the peripheral environment may be prevented from contamination. In addition, the first nozzle injects the etchant directly to the edge of the wafer to save the etchant.

As shown in FIG. 1, a second nozzle 600 injecting cleaning chemicals is used for cleaning the edge of the etched wafer 10. The second nozzle 600 may be moved by the second nozzle moving device 700. The second nozzle 600 has an identical structure to the first nozzle 400. However, the second nozzle 600 preferably injects cleaning chemicals unlike the first nozzle 400. The second nozzle moving device 700 has the same structure with the first nozzle moving device 500. Instead of the second nozzle 600 and the second nozzle moving device 700, the first nozzle 400 may have a third injection hole which sprays cleaning chemicals.

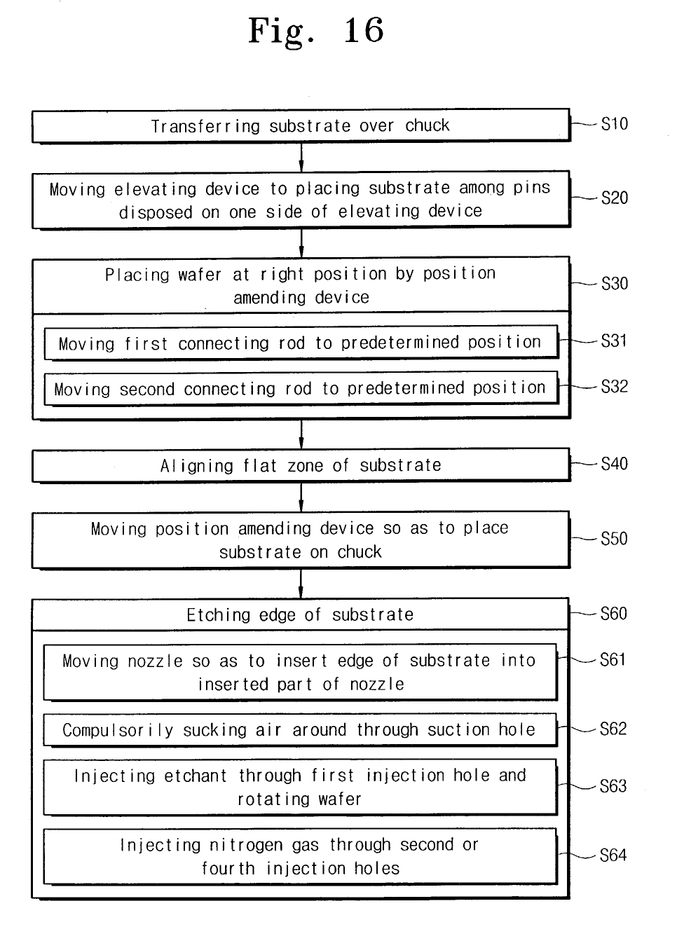

FIG. 16 is a flow chart showing steps of etching the edge of the wafer 10 using the apparatus 1 for manufacturing a semiconductor.

The wafer 10 is transferred over the chuck 800 by a transfer unit 20 such as a robot arm (step S10). The elevating device 300 transfers the position amending device 100 downward to place the wafer 10 at the grooves 119 of the pins 112, 114, 116 and 118 (step S20). The wafer 10 is placed at the right position by the position amending device 100 (step S30).

The steps for placing the wafer 10 at the right position by the position amending device 100 are as follows. First, the first and second pins 112 and 114 are moved to a predetermined position (step S31). Then, the third and fourth pins 116 and 118 are moved to the predetermined position. Thus, the wafer 10 is placed at the right position and held by the pins (step S32). To align a flat zone of the wafer at the right position, the parallel pin 210 of the flat zone alignment device 200 is moved toward the flat zone 12. The parallel pin 210 pushes an edge of the flat zone 12 to rotate it until the flat zone of the wafer 10 contacts with the parallel pin 210 in a plane (step S40). The elevating device 300 transfers the position amending device 100 downward to absorb the wafer 10 by vacuum on the chuck 800 (step S50). The edge of the wafer 10 using vacuum on the chuck 800 is etched by the first nozzle 400 (step S60).

The steps of etching the edge of the wafer 10 by the first nozzle 400 are as follows. The first nozzle 400 is moved so that the edge of the wafer 10 is inserted into the inserted part 460 (step S61). The first nozzle 400 draws the air around through the suction hole 430 by suction (step S62). The etchant is injected through the first injection hole 440 and the wafer 10 is rotated (step S63). The etchant etches the edge of back and front sides of the wafer and the sidewall thereof. Then, the etchant is drawn into the suction hole 430. The nitrogen gas is injected through the second injection hole 450 when the etchant is injected through the first injection hole 440. The nitrogen gas prevents the etchant from flowing out of the inserted part 460. The nitrogen gas may be injected through the fourth injection hole 160 of the position amending device 100.

According to the preferred embodiment, the position amending device 100 is transferred into the apparatus for manufacturing a semiconductor 1 and located over the wafer 10. However, the position amending device 100, having the pins, may be placed around the inner side of the chamber 900 where the chuck 800 is located.

According to the apparatus for manufacturing a semiconductor of the present invention, even though the wafer is transferred offset from the right position, the position of the wafer is changed. Thus, the center of the wafer is centered on the chuck to be exactly placed on the chuck. As a result, the edge of the wafer may be etched uniformly without over or under etching.

What is claimed is:

1. An apparatus for manufacturing a semiconductor comprising:
a chuck where a wafer is placed;
a position amending device having pins which move the wafer into a centered position on the chuck; and
a first nozzle for injecting a fluid at an edge of the wafer.

2. An apparatus according to claim 1, wherein the position amending device comprises:
a first through fourth pins disposed at four edges; and
a transfer apparatus moving the first through fourth pins to a predetermined position.

3. A device according to claim 2, wherein the transfer apparatus comprises:
a first connecting rod where the first and second pins are combined;
a second connecting rod where the third and fourth pins are combined;
a first moving rail guiding the first and second connecting rods; and
a first driving part driving the first and second connecting rods.

4. An apparatus according to claim 3, wherein the transfer apparatus further comprises a first stopper limiting movements of the first and second connecting rods.

5. An apparatus according to claim 4, wherein each of the first through fourth pins is rotatable about its own central axis and includes a motion associated with the first and second connecting rods.

6. An apparatus according to claim 1, wherein each of the first through fourth pins has a groove around a sidewall thereof configured to hold the wafer.

7. An apparatus according to claim 1, wherein the wafer includes a flat zone and the apparatus further comprises a flat zone alignment device for aligning the flat zone of the wafer to face a predetermined direction.

8. An apparatus according to claim 7, wherein the flat zone alignment device comprises:
a parallel pin;
a first bracket where the parallel pin is fixed;
a first feeding bar where the first bracket is fixed; and
a second driving part for moving the first feeding bar;
wherein the flat zone alignment device pushes one edge of the flat zone, such that the wafer is rotated until the flat zone of the wafer is in contact with a parallel surface of the parallel pin.

9. An apparatus according to claim 1, further comprising an elevating device for moving the position amending device up and down.

10. An apparatus according to claim 9, wherein the elevating device further comprises:
a second feeding bar fixed to the position amending device; and
a third driving part moving the second feeding bar.

11. An apparatus according to claim 10, wherein the elevating device further comprises a guide for leading the movement of the position amending device.

12. An apparatus according to claim 10, wherein the elevating device further comprises a second stopper for limiting the position amending device to be transferred over a predetermined distance.

13. An apparatus according to claim 1, further comprising a first nozzle moving device for transferring the first nozzle.

14. An apparatus according to claim 13, wherein the wafer includes a flat zone and the first nozzle is moved to etch the flat zone of the wafer in an identical width with to other edge-etched portions of the wafer.

15. An apparatus according to claim 14, wherein the first nozzle moving device comprises:
a second bracket where the first nozzle is connected;
a base having a second moving rail where the second bracket is connected; and
a fourth driving part for moving the second bracket.

16. An apparatus according to claim 1, wherein the first nozzle has an inserted part, which corresponds to the edge of the wafer when the in operation;
a first injection hole being formed on one side of the inserted part to inject a fluid to the edge of the wafer; and
a suction hole being formed on other side of the inserted part to suck the fluid injected to the edge of the wafer.

17. An apparatus according to claim 16, wherein the first injection hole is formed in a lower side of the inserted part; and
wherein the suction hole is formed in an upper side the inserted part.

18. An apparatus according to claim 17, wherein each of the upper and lower sides of the inserted part has a second injection hole for injecting gases to prevent the fluid injected through the first injection hole from flowing out of the inserted part of the first nozzle.

19. An apparatus according to claim 17, wherein each of the upper and lower sides of the inserted part has a third injection hole for injecting cleaning chemicals to clean the edge of the wafer.

20. An apparatus according to claim 13, further comprising:
a second nozzle for injecting cleaning chemicals to clean the edge of the wafer reacting with the fluid injected through the first nozzle; and
a second nozzle moving device for driving the second nozzle.

21. An apparatus according to claim 1, wherein the first nozzle injects an etchant to the edge of the wafer; and
wherein the position amending device further comprises a fourth injection hole for injecting gases to the wafer to prevent the fluid injected through the first nozzle from being splashed out of the first nozzle.

22. A method for manufacturing a semiconductor comprising the steps of:
transferring a wafer over a chuck;
transferring a position amending device by employing an elevating device to place the wafer among pins disposed at the position amending device;
moving the pins to place the wafer at a right or centered position and to hold the wafer;
moving the position amending device to place the wafer on the chuck; and
etching an edge of the wafer.

23. A method according to claim 22, wherein moving the pins to place the wafer at the right or centered position and to hold the wafer further comprises:
moving a first connecting rod to a predetermined position at the position amending device which includes the first connecting rod, a second connecting rod and a first moving rail, wherein the first connecting rod is where first and second pins are fixed and the second connecting rod is where the third and fourth pins are fixed and the first moving rail leads movements of the first and second connecting rods; and
moving the second connecting rod to a predetermined position to push the wafer, thereby placing the wafer at the right or centered position and holding the wafer by the first through fourth pins.

24. A method according to claim 22, further comprising aligning the flat zone of the wafer;
wherein the aligning the flat zone includes moving a parallel pin installed on a flat zone alignment device toward the flat zone and pushing one edge of the flat zone to rotate the wafer, until the parallel pin and the flat zone of the wafer are in contact with each other in a plane.

25. A method according to claim 24, wherein etching the edge of the wafer further comprises:
moving the first nozzle along a straight line to insert the wafer into an inserted part of the first nozzle, a first injection hole being formed on an upper side thereof and a suction hole being formed on a lower side thereof;
compulsorily sucking the air through the suction hole;
injecting an etchant through the first injection hole and rotating the wafer; and
compulsorily sucking the etchant through the suction hole.

26. A method according to claim 24, further comprising injecting gas through second injection holes formed in the upper and lower sides of the inserted part to prevent the etchant from flowing out of the inserted part of the first nozzle.
